(19) United States
(12) Patent Application Publication
(10) Pub. No.: US 2024/0235491 A9
(43) Pub. Date: Jul. 11, 2024

(54) POWER AMPLIFIER CIRCUIT

(71) Applicant: Murata Manufacturing Co., Ltd., Nagaokakyo-shi (JP)

(72) Inventors: Naofumi TAKEZONO, Nagaokakyo-shi (JP); Shunji YOSHIMI, Nagaokakyo-shi (JP)

(73) Assignee: Murata Manufacturing Co., Ltd., Nagaokakyo-shi (JP)

(21) Appl. No.: 18/403,741

(22) Filed: Jan. 4, 2024

Related U.S. Application Data
(63) Continuation of application No. PCT/JP2022/032045, filed on Aug. 25, 2022.

(30) Foreign Application Priority Data
Aug. 26, 2021 (JP) 2021-138100

(51) Int. Cl. H03F 1/26; H03F 3/24

(52) U.S. Cl. CPC H03F 1/26; H03F 3/245; H03F 2200/294; H03F 2200/451

(57) ABSTRACT

A power amplifier circuit includes a first amplifier, a second amplifier, a third amplifier, and a harmonic suppression circuit. The first amplifier operates on power supplied through a first supply line, and amplifies a first transmit signal in a first frequency band. The second amplifier operates on power supplied through a second supply line connected to the first supply line, and amplifies a second transmit signal in a second frequency band different from the first frequency band. The third amplifier shares an antenna with the second amplifier, and amplifies a receive signal in the second frequency band received from the antenna. The harmonic suppression circuit generates, based on a harmonic of the first transmit signal, a suppression signal to suppress the harmonic to be transferred to the first supply line, and outputs the suppression signal to the first supply line or the second supply line.

### CROSS-REFERENCE TO RELATED APPLICATIONS

This application is a continuation of international application no. PCT/JP2022/032045, filed Aug. 25, 2022, and which claims the benefit of priority to Japanese application no. JP 2021-138100, filed Aug. 26, 2021. The entire contents of both prior applications are hereby incorporated by reference.

### TECHNICAL FIELD

The present disclosure relates to a power amplifier circuit.

### BACKGROUND ART

Some existing communication modules support multiple bands of radio frequency (RF).

### CITATION LIST

### Patent Document

Patent Document 1: Japanese Unexamined Patent Application Publication No. 2018-098578

### SUMMARY

### Technical Problem

A communication module as discussed above supports three bands. A low noise amplifier that amplifies a receive signal, and a power amplifier that amplifies a transmit signal are provided for each of the three bands. The low noise amplifier and the power amplifier are connected to each other through a duplexer.

A situation may arise where, when a power amplifier is in operation, a harmonic of a transmit signal is transferred to another element as noise through a supply line that supplies power to the power amplifier. For example, if two power amplifiers share a single power supply, noise is transferred from one of the two power amplifiers to the other power amplifier through the supply line. The noise transferred to the other power amplifier is further transferred through the duplexer to the low noise amplifier. Such noise is undesirable as the noise leads to performance degradation of the power amplifier and the low noise amplifier.

The present disclosure has been made in view of the circumstances mentioned above. Accordingly, one of the objects of the present disclosure to provide a power amplifier circuit including a first amplifier that amplifies a transmit signal in a first frequency band, and a second amplifier and a third amplifier that respectively amplify a transmit signal and a receive signal in a second frequency band different from the first frequency band, the power amplifier circuit being configured to enable suppression of noise that is transferred from the first amplifier to the second amplifier and the third amplifier.

### Solution to Problem

A power amplifier circuit according to an aspect of the present disclosure includes a first amplifier, a second amplifier, a third amplifier, and a harmonic suppression circuit. The first amplifier operates on power supplied through a first supply line, and amplifies a first transmit signal in a first frequency band. The second amplifier operates on power supplied through a second supply line connected to the first supply line, and amplifies a second transmit signal in a second frequency band different from the first frequency band. The third amplifier shares an antenna with the second amplifier, and amplifies a receive signal in the second frequency band received from the antenna. The harmonic suppression circuit generates, based on a harmonic of the first transmit signal, a suppression signal to suppress the harmonic to be transferred to the first supply line, and outputs the suppression signal to the first supply line or the second supply line.

A power amplifier circuit according to another aspect of the present disclosure includes a first amplifier, a second amplifier, a third amplifier, a first coupler, a second coupler, a phase shifting circuit, and an attenuation circuit. The first amplifier receives supply of power through a first supply line, and amplifies a first transmit signal in a first frequency band. The second amplifier receives supply of power through a second supply line connected to the first supply line, and amplifies a second transmit signal in a second frequency band different from the first frequency band. The third amplifier shares an antenna with the second amplifier, and amplifies a receive signal in the second frequency band received from the antenna. The first coupler couples to a signal line through which the first transmit signal amplified by the first amplifier is transferred. The second coupler couples to the first supply line or the second supply line. The phase shifting circuit is disposed between the first coupler and the second coupler. The attenuation circuit is disposed between the first coupler and the second coupler.

A power amplifier circuit according to another aspect of the present disclosure includes a first amplifier, a second amplifier, a third amplifier, a first coupler, and a second coupler. The first amplifier receives supply of power through a first supply line, and amplifies a first transmit signal in a first frequency band. The second amplifier receives supply of power through a second supply line connected to the first supply line, and amplifies a second transmit signal in a second frequency band different from the first frequency band. The third amplifier shares an antenna with the second amplifier, and amplifies a receive signal in the second frequency band received from the antenna. The first coupler includes a third resistance element. The third resistance element has a first end connected to an input of the first amplifier, and a second end. The second coupler includes a second sub-line that is connected to the second end of the third resistance element, and that electromagnetically couples to the first supply line or the second supply line.

### Advantageous Effects

The present disclosure makes it possible to provide a power amplifier circuit including a first amplifier that amplifies a first transmit signal in a first frequency band, and a second amplifier and a third amplifier that respectively amplify a second transmit signal and a receive signal in a second frequency band different from the first frequency band, the power amplifier circuit being configured to enable suppression of noise that is transferred from the first amplifier to the second amplifier and the third amplifier.

### BRIEF DESCRIPTION OF DRAWINGS

FIG. 1 is a circuit diagram of a power amplifier circuit 11 in a communication device 1.

FIG. 2 is a circuit diagram of a harmonic suppression circuit 141 and circuitry in its vicinity in a front-end module 101.

FIG. 3 is a circuit diagram of a harmonic suppression circuit 142 and circuitry in its vicinity in the front-end module 101.

FIG. 4 is a circuit diagram of a harmonic suppression circuit 143 and circuitry in its vicinity in the front-end module 101.

FIG. 5 is a circuit diagram of a harmonic suppression circuit 144 and circuitry in its vicinity in the front-end module 101.

FIG. 6 is a circuit diagram of a harmonic suppression circuit 145 and circuitry in its vicinity in the front-end module 101.

FIG. 7 is a circuit diagram of a harmonic suppression circuit 146 and circuitry in its vicinity in the front-end module 101.

### DETAILED DESCRIPTION

Exemplary embodiments of the present disclosure are described below in detail with reference to the drawings. Identical elements are designated by the same reference signs to minimize redundant descriptions.

As used herein, the term “connection” or any other such term means that circuit components such as elements, signal lines, and power supply lines have direct or indirect physical or electrical connection with each other. The term “coupling” or any other such term as used herein is meant to include “connection” mentioned above, and electromagnetic coupling (such as one provided by a coupler through which a RF signal such as a harmonic signal is transferred from one circuit element to the other).

### First Embodiment

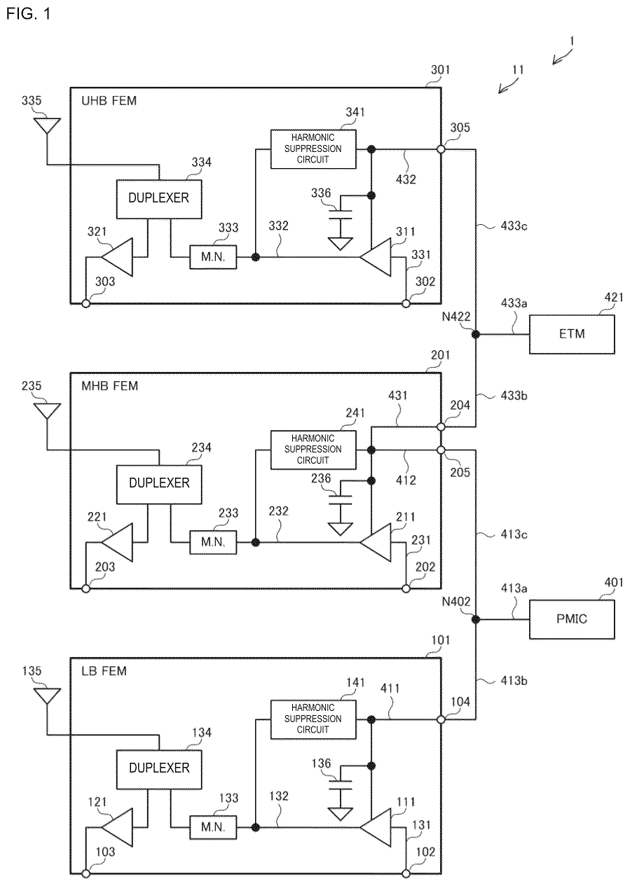

A power amplifier circuit 11 according to a first exemplary embodiment is described below. FIG. 1 is a circuit diagram of the power amplifier circuit 11 in a communication device 1. As illustrated in FIG. 1, the communication device 1 includes the power amplifier circuit 11, antennas 135, 235 and 335, a power management integrated circuit (PMIC) 401, and an envelope tracking modulator (ETM) 421.

The communication device 1 is a mobile communication unit such as a cellular phone. The power amplifier circuit 11 includes the following major components: a power amplifier 111 (first amplifier), a power amplifier 211 (first amplifier/second amplifier), a power amplifier 311 (second amplifier), a low noise amplifier 121, a low noise amplifier 221 (third amplifier), a low noise amplifier 321 (third amplifier), a matching circuit 133, a matching circuit 233, a matching circuit 333, a duplexer 134, a duplexer 234, a duplexer 334, a capacitor 136 (third capacitor), a capacitor 236 (third capacitor), a capacitor 336, a harmonic suppression circuit 141, a harmonic suppression circuit 241, and a harmonic suppression circuit 341.

According to the first exemplary embodiment, the power amplifier circuit 11 is divided into the following three front-end modules: a front-end module 101 for the low band (LB); a front-end module 201 for the mid-high band (MHB); and a front-end module 301 for the ultra-high band (UHB).

For the front-end module 101, for example, frequency division duplexing is employed such that a common antenna 135 is used for both transmission and reception of a RF signal. For the front-end modules 201 and 301, likewise, a common antenna 235 and a common antenna 335 are respectively used for both transmission and reception of a RF signal.

The front-end module 101 is provided with the following components: the power amplifier 111, the low noise amplifier 121, the matching circuit 133, the duplexer 134, the capacitor 136, and the harmonic suppression circuit 141.

The front-end module 201 is provided with the following components: the power amplifier 211, the low noise amplifier 221, the matching circuit 233, the duplexer 234, the capacitor 236, and the harmonic suppression circuit 241.

The front-end module 301 is provided with the following components: the power amplifier 311, the low noise amplifier 321, the matching circuit 333, the duplexer 334, the capacitor 336, and the harmonic suppression circuit 341.

The power amplifier 111 of the front-end module 101 amplifies a transmit signal supplied through a transmit-signal input terminal 102, and outputs the amplified transmit signal to the duplexer 134 through the matching circuit 133.

The duplexer 134 outputs, to the antenna 135, the transmit signal supplied from the power amplifier 111. The duplexer 134 also outputs, upon receiving supply of a receive signal from the antenna 135, the receive signal to the low noise amplifier 121.

The low noise amplifier 121 amplifies the receive signal supplied from the duplexer 134, and outputs the amplified receive signal to a receive-signal output terminal 103. The capacitor 136 will be described later.

A transmit-signal input terminal 202, a receive-signal output terminal 203, the power amplifier 211, the low noise amplifier 221, the matching circuit 233, the duplexer 234, the antenna 235, and the capacitor 236 in the front-end module 201 are respectively similar in function to the power amplifier 111, the low noise amplifier 121, the matching circuit 133, the duplexer 134, and the antenna 135.

A transmit-signal input terminal 302, a receive-signal output terminal 303, the power amplifier 311, the low noise amplifier 321, the matching circuit 333, the duplexer 334, the antenna 335, and the capacitor 336 in the front-end module 301 are respectively similar in function to the power amplifier 111, the low noise amplifier 121, the matching circuit 133, the duplexer 134, and the antenna 135.

The PMIC 401 supplies power at a certain voltage to a power supply terminal 104 of the power amplifier 111, and to a power supply terminal 205 of the front-end module 201.

According to the first exemplary embodiment, the power supply terminal 104 is connected to the PMIC 401 through a power supply line 413b (first supply line) and a power supply line 413a. The power supply terminal 205 is connected through a power supply line 413c (second supply line) to the junction point (hereinafter sometimes referred to as node N402) of the power supply line 413b and the power supply line 413a.

The power amplifier 111 operates on power supplied from the power supply terminal 104 through a power supply line 411 (first supply line). The power amplifier 211 operates on power supplied from the power supply terminal 205 through a power supply line 412 (second supply line).

The ETM 421 supplies power at a voltage according to the amplitude of a transmit signal, to a power supply terminal 204 of the front-end module 201 and to a power supply terminal 305 of the front-end module 301.

According to the first exemplary embodiment, the power supply terminal 204 is connected to the ETM 421 through a power supply line 433b (first supply line) and a power supply line 433a. The power supply terminal 305 is connected through a power supply line 433c (second supply line) to the junction point (hereinafter sometimes referred to as node N422) of the power supply line 433b and the power supply line 433a.

The power amplifier 211 operates also on power supplied from the power supply terminal 204 through a power supply line 431 (first supply line). The power amplifier 311 operates on power supplied from the power supply terminal 305 through a power supply line 432 (second supply line).

The communication device 1 is, for example, capable of connecting to both LTE (4G) and New Radio (NR) (5G) by means of E-UTRAN New Radio-Dual Connectivity (EN-DC).

Specifically, the communication device 1 allows for, for example, simultaneous transmission/reception of Band n3, which is the mid-band of the front-end module 201, and Band 8, which is the low band of the front-end module 101, by means of EN-DC. The term “simultaneous” in this case is meant to include not only cases where a period in which a transmitting operation is being performed and a period in which a receiving operation is being performed completely coincide with each other, but also cases where a receiving operation is being performed in at least part of the period in which a transmitting operation is being performed or where a transmitting operation is being performed in at least part of the period in which a receiving operation is being performed.

A situation where the mid-band Band n3 and the low band TURAN 8 are transmitted/received simultaneously can occur accidentally or non-accidentally. For example, if the front-end module 101 and the front-end module 201 are controlled independently of each other, Band n3 and Band 8 are accidentally transmitted/received simultaneously. If the front-end module 101 and the front-end module 201 are controlled integrally, Band n3 and Band 8 are non-accidentally transmitted/received simultaneously.

Band n3 has a receive frequency band (second frequency band) of 1805 to 1880 MHz, and Band 8 has a frequency band (first frequency band) of 880 to 915 MHz. Accordingly, the frequency band of a receive signal in the front-end module 201 overlaps the frequency band of the second harmonic (i.e., 1760 to 1830 MHz) of a transmit signal (first transmit signal) in the front-end module 101.

In this case, the second harmonic of a transmit signal amplified by the power amplifier 111 of the front-end module 101 is transferred to the power amplifier 211 of the front-end module 201 through the power supply lines 411, 413b, 413c, and 412. The second harmonic transferred to the power amplifier 211 is transferred to the low noise amplifier 221 through the duplexer 234. The second harmonic from the power amplifier 111 causes performance degradation of the power amplifier 211 and the low noise amplifier 221.

In particular, if amplification of a transmit signal by the power amplifier 111, and amplification of a receive signal by the low noise amplifier 221 occur simultaneously, the second harmonic causes degradation of the amplification characteristics of the low noise amplifier 221, leading to degraded quality of the receive signal.

The communication device 1 allows for, for example, simultaneous transmission/reception of Band n79, which is the ultra-high band of the front-end module 301, and Band 40, which is the high band of the front-end module 201, by means of EN-DC.

Band n79 has a receive frequency band (second frequency band) of 4400 to 5000 MHz, and Band 40 has a frequency band (first frequency band) of 2300 to 2400 MHz. Accordingly, the frequency band of a receive signal in the front-end module 301 overlaps the frequency band of the second harmonic (i.e., 4600 to 4800 MHz) of a transmit signal (first transmit signal) in the front-end module 201.

The communication device 1 allows for, for example, simultaneous transmission/reception of Band n78, which is the ultra-high band of the front-end module 301, and Band 3, which is the mid-band of the front-end module 201, by means of EN-DC.

Band n78 has a receive frequency band (second frequency band) of 3300 to 3800 MHz, and Band 3 has a frequency band (first frequency band) of 1710 to 1785 MHz. Accordingly, the frequency band of a receive signal in the front-end module 301 overlaps the frequency band of the second harmonic (i.e., 3420 to 3570 MHz) of a transmit signal (first transmit signal) in the front-end module 201.

In the above-mentioned cases, the second harmonic of a transmit signal amplified by the power amplifier 211 of the front-end module 201 is transferred to the power amplifier 311 of the front-end module 301 through the power supply lines 431, 433b, 433c, and 432. The second harmonic transferred to the power amplifier 311 is transferred to the low noise amplifier 321 through the duplexer 334. This is undesirable because the second harmonic from the power amplifier 211 causes performance degradation of the power amplifier 311 and the low noise amplifier 321.

The situation mentioned above is particularly undesirable if amplification of a transmit signal by the power amplifier 211, and amplification of a receive signal by the low noise amplifier 321 occur simultaneously, because the second harmonic causes degradation of the amplification characteristics of the low noise amplifier 321, leading to degraded quality of the receive signal.

In the power amplifier circuit 11, a harmonic suppression circuit is disposed between a signal line that transfers a transmit signal, and a power supply line to thereby suppress a harmonic of the transmit signal that is transferred to the power supply line. The harmonic suppression circuit is now described below in detail.

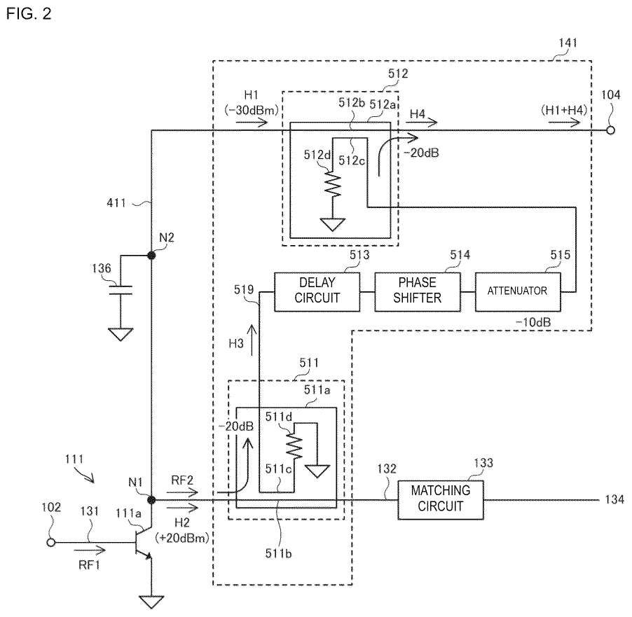

FIG. 2 is a circuit diagram of the harmonic suppression circuit 141 and circuitry in its vicinity in the front-end module 101. Since the harmonic suppression circuits 241 and 341 are similar in configuration to the harmonic suppression circuit 141, the harmonic suppression circuit 141 is described below as a representative example, and descriptions of the harmonic suppression circuits 241 and 341 are omitted.

As illustrated in FIG. 2, the power amplifier 111 includes an amplifier transistor 111a. The amplifier transistor 111a is implemented by, for example, a bipolar transistor such as a heterojunction bipolar transistor (HBT). Alternatively, a transistor such as the amplifier transistor 111a may be implemented by another transistor such as a metal-oxide-semiconductor field-effect transistor (MOSFET). In this case, base, collector, and emitter may be respectively read as gate, collector, and source.

The amplifier transistor 111a has a base, a collector, and an emitter. The base is connected to the transmit-signal input terminal 102 through a signal line 131. The collector is connected to the power supply terminal 104 through the power supply line 411. The emitter is connected to ground.

A signal line 132 connects a node N1, which is located on the power supply line 411, and the duplexer 134 to each other. The matching circuit 133 is disposed on the signal line 132, and has a first end and a second end. The first end is connected to the node N1. The second end is connected to the duplexer 134. The matching circuit 133 matches impedance between the amplifier transistor 111a and the duplexer 134.

When the amplifier transistor 111a receives a RF signal RF1 supplied to its base, the amplifier transistor 111a amplifies the RF signal RF1 to provide an amplified signal RF2 (first transmit signal), which is then output from the collector of the amplifier transistor 111a to the duplexer 134 through the signal line 132. The amplified signal RF2 includes a second harmonic H2. The second harmonic H2 has a power of, for example, 20 dBm.

A second harmonic H1 based on the amplified signal RF2 is transferred from the node N1 to the power supply terminal 104 through the power supply line 411.

The capacitor 136 has a first end and a second end. The first end is connected to a node N2 on the power supply line 411. The second end is connected to ground. The capacitor 136 serves as a filter for attenuating the second harmonic H1. The node N2 is located between the node N1 and the power supply terminal 104.

The capacitor 136 attenuates, for example, the power of the second harmonic H1 to −30 dBm. The power supply line 411 may be provided with a choke coil located between the node N1 and the node N2.

The harmonic suppression circuit 141 is disposed between the power supply line 411 and the signal line 132. The harmonic suppression circuit 141 generates, based on a portion of the second harmonic H2 that is transferred to the signal line 132, a suppression signal for suppressing the second harmonic H1 that is transferred to the power supply line 411. The harmonic suppression circuit 141 outputs the generated suppression signal to the power supply line 411.

According to the first exemplary embodiment, the harmonic suppression circuit 141 includes a first coupling unit 511, a second coupling unit 512, a delay circuit 513, a phase shifter 514 (phase shifting circuit), an attenuator 515 (attenuation circuit), and a suppression signal line 519.

The suppression signal line 519 has a first end and a second end. The first end is connected to the first coupling unit 511. The second end is connected to the second coupling unit 512. On the suppression signal line 519, the delay circuit 513, the phase shifter 514, and the attenuator 515 are arranged in decreasing order of proximity to the first coupling unit 511. The delay circuit 513, the phase shifter 514, and the attenuator 515 may be arranged in a different order.

The first coupling unit 511 couples to the signal line 132 that transfers the amplified signal RF2 amplified by the amplifier transistor 111a. According to the first exemplary embodiment, the first coupling unit 511 includes a directional coupler 511a disposed on the signal line 132 between the node N1 and the matching circuit 133.

The directional coupler 511a includes a main line 511b, a sub-line 511c (first sub-line), and a resistance element 511d. The main line 511b constitutes a portion of the signal line 132. The sub-line 511c electromagnetically couples to the main line 511b.

The main line 511b has a first port and a second port. The first port is connected to the node N1. The second port is connected to the first end of the matching circuit 133. The sub-line 511c has a third port and a fourth port. The third port is connected to the first end of the suppression signal line 519. The fourth port is grounded via the resistance element 511d. The fourth port is an isolated port with respect to the first port.

The second harmonic H2 is input to the first port of the main line 511b of the directional coupler 511a. A second harmonic H3, which has a power 20 dB lower than the power of the second harmonic H2, is output from the third port of the sub-line 511c of the directional coupler 511a.

The second coupling unit 512 couples to the power supply line 411 between the node N2 and the power supply terminal 104. According to the first exemplary embodiment, the second coupling unit 512 includes a directional coupler 512a located on the power supply line 411.

The directional coupler 512a includes a main line 512b, a sub-line 512c (second sub-line), and a resistance element 512d. The main line 512b constitutes a portion of the power supply line 411. The sub-line 512c electromagnetically couples to the main line 512b.

The main line 512b has a first port and a second port. The first port is connected to the power supply terminal 104. The second port is connected to the node N2. The sub-line 512c has a third port and a fourth port. The third port is connected to the second end of the suppression signal line 519. The fourth port is grounded via the resistance element 512d. The second port is an isolated port with respect to the third port.

A second harmonic (hereinafter sometimes referred to as second harmonic H4) having a power that is 20 dB lower than the power of the second harmonic H3 input to the third port of the sub-line 512c is output as a suppression signal from the first port of the main line 512b. The second harmonic H4 becomes superposed on the second harmonic H1 in the second coupling unit 512. Accordingly, the second harmonic (H1+H4) resulting from the superposition of the two harmonics can be reduced in power as will be described later. As a result, the second harmonic (H1+H4) at reduced power is output to the power supply terminal 104, or virtually no second harmonic (H1+H4) is output to the power supply terminal 104. This helps to reduce the likelihood of noise being transferred to the following power supply lines: the power supply line 411; the power supply line 413a connected to the power supply line 411; and the power supply line 412.

The delay circuit 513 is, for example, a delay line for delaying the second harmonic H3. The delay circuit 513 adjusts the line length of the suppression signal line 519 from the first coupling unit 511 to the second coupling unit 512, so that in the second coupling unit 512, the second harmonic H1 and the second harmonic H4 are aligned in phase with each other.

The phase shifter 514 shifts the phase of the second harmonic H3. According to the first exemplary embodiment, for example, the phase shifter 514 causes the amplitude of the second harmonic H3 to be inverted by introducing a phase shift of approximately 180 degrees between the phase of the second harmonic H3 before being input to the phase shifter 514 and the phase of the second harmonic H3 after being output from the phase shifter 514. This allows the amplitude of the second harmonic H1 and the amplitude of the second harmonic H4 to have opposite signs in the second coupling unit 512. As a result, the second harmonic H1 can be reduced in power by means of the second harmonic H4.

The attenuator 515 attenuates, for example, the power of the second harmonic H3 so that in the second coupling unit 512, the power of the second harmonic H1 and the power of the second harmonic H4 are substantially equal. According to the first exemplary embodiment, for example, the attenuator 515 outputs, to the second coupling unit 512, the second harmonic H3 having a power that is 10 dB lower than the power of the second harmonic H3 input from the phase shifter 514. As a result, the second harmonic H4 to be output from the first port of the main line 512b can be made to have a power of −30 dBm, which is substantially equal to the power of the second harmonic H1 that is input to the main line 512b. This allows for effective suppression of the second harmonic (H1+H4) that is transferred to the power supply line 411.

### Second Embodiment

The power amplifier circuit 11 according to a second exemplary embodiment is described below. In the second and subsequent exemplary embodiments, matters or features identical to those in the first exemplary embodiment are not described, and only differences from the first exemplary embodiment are described. In particular, the same or similar operational effects provided by the same or similar features are not mentioned for each individual exemplary embodiment.

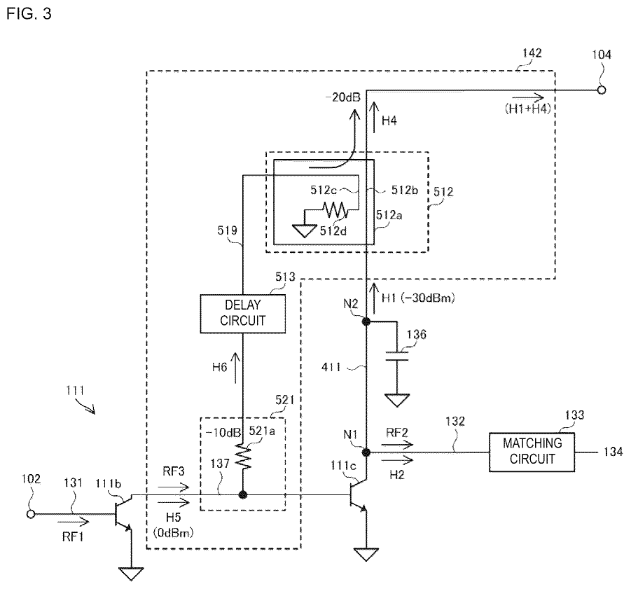

FIG. 3 is a circuit diagram of a harmonic suppression circuit 142 and circuitry in its vicinity in the front-end module 101. As illustrated in FIG. 3, the power amplifier circuit 11 according to the second exemplary embodiment differs from the power amplifier circuit 11 according to the first exemplary embodiment in that the harmonic suppression circuit 142 is disposed between a signal line 137, which is a line through which a signal is transferred before undergoing amplification, and the power supply line 411.

According to the second exemplary embodiment, the power amplifier 111 includes a driver-stage transistor 111b (fourth amplifier) and a power-stage transistor 111c (first amplifier). The matching circuit 133 and the capacitor 136 are respectively similar in function to the matching circuit 133 and the capacitor 136 illustrated in FIG. 2.

The driver-stage transistor 111b has a base, a collector, and an emitter. The base is connected to the transmit-signal input terminal 102 through the signal line 131. The collector is connected to the signal line 137. The emitter is connected to ground. A power supply line (not illustrated) is connected to the collector of the driver-stage transistor 111b.

The power-stage transistor 111c has a base, a collector, and an emitter. The base is connected to the collector of the driver-stage transistor 111b through the signal line 137. The collector is connected to the power supply terminal 104 through the power supply line 411. The emitter is connected to ground.

When the driver-stage transistor 111b receives the RF signal RF1 supplied to its base, the driver-stage transistor 111b amplifies the RF signal RF1 to provide an amplified signal RF3, which is then output from the collector of the driver-stage transistor 111b to the base of the power-stage transistor 111c through the signal line 137. The amplified signal RF3 includes a second harmonic H5. The second harmonic H5 has a power of, for example, 0 dBm.

The power-stage transistor 111c is an inverting amplifier that operates as a circuit whose collector serves as the output and whose emitter is grounded. Upon supply of the amplified signal RF3 to the base of the power-stage transistor 111c, the amplified signal RF3 is inverting-amplified, and the resulting amplified signal RF2 (first transmit signal) is output from the collector of the power-stage transistor 111c to the matching circuit 133 through the signal line 132.

The second harmonic H1 based on the second harmonic H2 output from the collector of the power-stage transistor 111c is transferred from the node N1 to the power supply terminal 104 through the power supply line 411. The capacitor 136 attenuates, for example, the power of the second harmonic H1 to −30 dBm.

According to the second exemplary embodiment, the harmonic suppression circuit 142 is disposed between the power supply line 411, and the signal line 137 through which the amplified signal RF2 before undergoing amplification by the power-stage transistor 111c, that is, the amplified signal RF3, is transferred.

The harmonic suppression circuit 142 includes a first coupling unit 521, the second coupling unit 512, the delay circuit 513, and the suppression signal line 519.

The suppression signal line 519 has a first end and a second end. The first end is connected to the first coupling unit 521. The second end is connected to the second coupling unit 512. The suppression signal line 519 is provided with the delay circuit 513.

The first coupling unit 521 includes a resistance element 521a (third resistance element). The resistance element 521a has a first end and a second end. The first end is connected to the signal line 137. The second end is connected to the first end of the suppression signal line 519. For example, the resistance element 521a has a resistance of several kilo-ohms, and is used for isolation between the suppression signal line 519 and the signal line 137.

A portion of the second harmonic H5 transferred to the signal line 137 passes through the resistance element 521a and the suppression signal line 519 toward the second coupling unit 512. Hereinafter, such a second harmonic that passes through the resistance element 521a and the suppression signal line 519 is sometimes referred to as second harmonic H6. The second harmonic H6 having a power that is 10 dB lower than the power of the second harmonic H5 is output from the second end of the resistance element 521a.

The second coupling unit 512 includes the directional coupler 512a. The main line 512b of the directional coupler 512a has a first port and a second port. The first port is connected to the power supply terminal 104. The second port is connected to the node N2. The sub-line 512c has a third port and a fourth port. The third port is connected to the second end of the suppression signal line 519. The fourth port is grounded via the resistance element 512d. The second port is an isolated port with respect to the third port.

The second harmonic H4 is output from the first port of the main line 512b. The second harmonic H4 has a power that is 20 dB lower than the power of the second harmonic H6 input to the third port of the sub-line 512c. The second harmonic H4 becomes superposed on the second harmonic H1 in the second coupling unit 512. Accordingly, the second harmonic (H1+H4) resulting from the superposition of the two harmonics can be reduced in power as will be described later. As a result, the second harmonic (H1+H4) at reduced power is output to the power supply terminal 104, or virtually no second harmonic (H1+H4) is output to the power supply terminal 104. This helps to reduce the likelihood of noise being transferred to the following power supply lines: the power supply line 411; the power supply line 413a connected to the power supply line 411; and the power supply line 412.

The second harmonic H1 and the second harmonic H4 in the second coupling unit 512 are aligned in phase with each other by means of the delay circuit 513.

The inverting amplification applied to the amplified signal RF3 by the power-stage transistor 111c causes the amplified signal RF3 and the amplified signal RF2 to have opposite phases. As a result, even with no phase shifter provided, the amplitude of the second harmonic H1 and the amplitude of the second harmonic H4 can be made to have opposite signs in the second coupling unit 512.

As described above, the second harmonic H5 before undergoing amplification by the power-stage transistor 111c is passed through the resistance element 521a to thereby generate the second harmonic H6. This means that, even with no attenuator provided, the power of the second harmonic H4 that is output from the first port of the main line 512b, and the power of the second harmonic H1 that is input to the main line 512b can be made substantially equal. As a result, through simple configuration, the second harmonic H1 that is transferred to the power supply line 411 can be effectively suppressed by means of the second harmonic H4.

### Third Embodiment

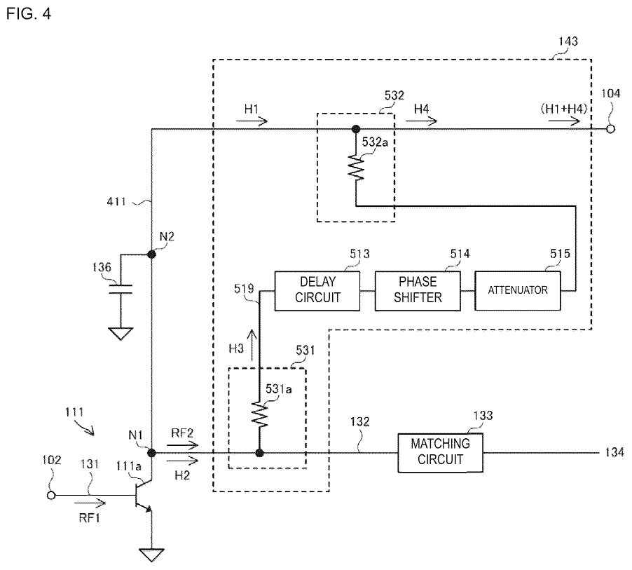

The power amplifier circuit 11 according to a third exemplary embodiment is described below. FIG. 4 is a circuit diagram of a harmonic suppression circuit 143 and circuitry in its vicinity in the front-end module 101. As illustrated in FIG. 4, the power amplifier circuit 11 according to the third exemplary embodiment differs from the power amplifier circuit 11 according to the first exemplary embodiment in that the suppression signal line 519 in the harmonic suppression circuit 143 is connected at one end to the signal line 132 through a resistance element, and at the other end to the power supply line 411 through a resistance element.

As compared with the harmonic suppression circuit 141 illustrated in FIG. 1, the harmonic suppression circuit 143 includes a first coupling unit 531 and a second coupling unit 532, instead of the first coupling unit 511 and the second coupling unit 512, respectively.

The first coupling unit 531 includes a resistance element 531a (first resistance element). The resistance element 531a has a first end and a second end. The first end is connected to the signal line 132 between the node N1 and the matching circuit 133. The resistance element 532a is used for, for example, isolation between the suppression signal line 519 and the signal line 132.

The second coupling unit 532 includes a resistance element 532a (second resistance element). The resistance element 532a has a first end and a second end. The first end is connected to the second end of the resistance element 531a through the delay circuit 513, the phase shifter 514, and the attenuator 515. The second end is connected to the power supply line 411 between the node N2 and the power supply terminal 104. The resistance element 532a is used for, for example, isolation between the suppression signal line 519 and the power supply line 411.

As described above, the suppression signal line 519 in the harmonic suppression circuit 143 is connected at one end to the signal line 132 through the resistance element 531a, and at the other end to the power supply line 411 through the resistance element 532a. This configuration allows for reduced size of the harmonic suppression circuit 143 relative to the harmonic suppression circuit 141 (see FIG. 2).

### Fourth Embodiment

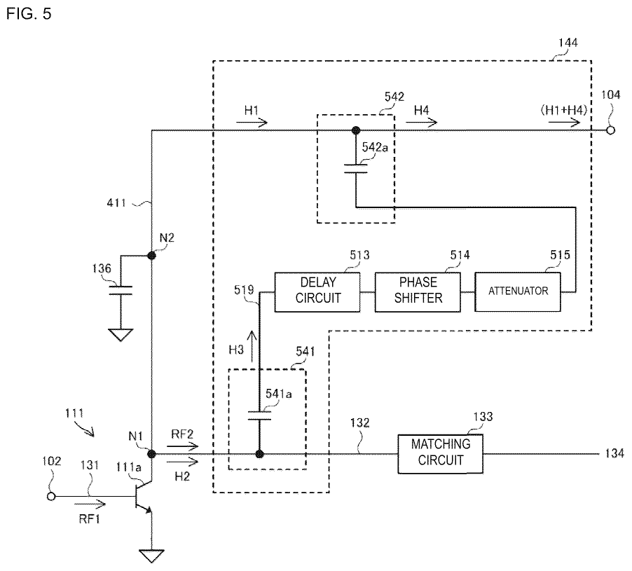

The power amplifier circuit 11 according to a fourth exemplary embodiment is described below. FIG. 5 is a circuit diagram of a harmonic suppression circuit 144 and circuitry in its vicinity in the front-end module 101. As illustrated in FIG. 5, the power amplifier circuit 11 according to the fourth exemplary embodiment differs from the power amplifier circuit 11 according to the first exemplary embodiment in that the suppression signal line 519 in the harmonic suppression circuit 144 is connected at one end to the signal line 132 through a capacitor, and at the other end to the power supply line 411 through a capacitor.

As compared with the harmonic suppression circuit 141 illustrated in FIG. 1, the harmonic suppression circuit 144 includes a first coupling unit 541 and a second coupling unit 542, instead of the first coupling unit 511 and the second coupling unit 512, respectively.

The first coupling unit 541 includes a capacitor 541a (first capacitor). The capacitor 541a has a first end and a second end. The first end is connected to the signal line 132 between the node N1 and the matching circuit 133. For example, the capacitor 541a is used for isolation between the suppression signal line 519 and the signal line 132 with respect to direct-current components and low-frequency alternating-current components, and conducts high-frequency alternating-current components such as the second harmonic H2.

The second coupling unit 542 includes a capacitor 542a (second capacitor). The capacitor 542a has a first end and a second end. The first end is connected to the second end of the capacitor 541a through the delay circuit 513, the phase shifter 514, and the attenuator 515. The second end is connected to the power supply line 411 between the node N2 and the power supply terminal 104. For example, the capacitor 542a is used for isolation between the suppression signal line 519 and the power supply line 411 with respect to direct-current components and low-frequency alternating-current components, and conducts high-frequency alternating-current components such as the second harmonic H2.

As described above, the suppression signal line 519 in the harmonic suppression circuit 144 is connected at one end to the signal line 132 through the capacitor 541a, and at the other end to the power supply line 411 through the capacitor 542a. This configuration allows for reduced size of the harmonic suppression circuit 144 relative to the harmonic suppression circuit 141 (see FIG. 2).

### Fifth Embodiment

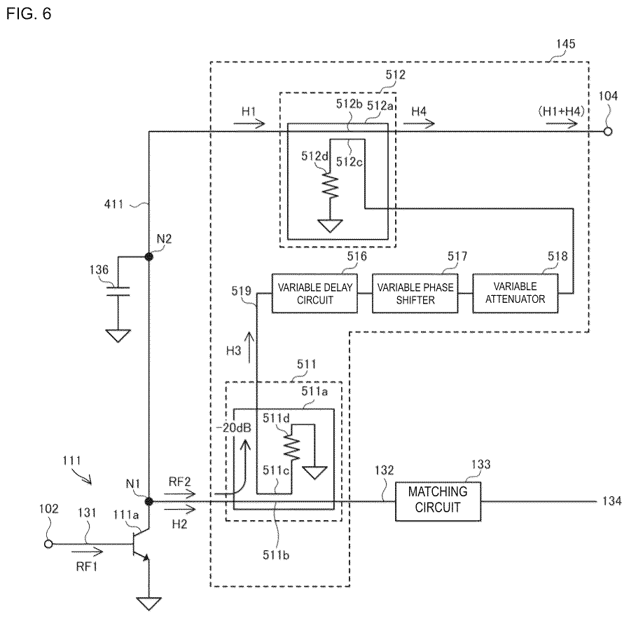

The power amplifier circuit 11 according to a fifth exemplary embodiment is described below. FIG. 6 is a circuit diagram of a harmonic suppression circuit 145 and circuitry in its vicinity in the front-end module 101. As illustrated in FIG. 6, the power amplifier circuit 11 according to the fifth exemplary embodiment differs from the power amplifier circuit 11 according to the first exemplary embodiment in that a delay circuit, a phase shifter, and an attenuator in the harmonic suppression circuit 145 are of a variable type.

As compared with the harmonic suppression circuit 141 illustrated in FIG. 1, the harmonic suppression circuit 145 includes a variable delay circuit 516, a variable phase shifter 517 (variable phase shifting circuit), and a variable attenuator 518, instead of the delay circuit 513, the phase shifter 514, and the attenuator 515, respectively.

The variable delay circuit 516 is a circuit capable of adjusting the amount of delay in the second harmonic H3. According to the fifth exemplary embodiment, the variable delay circuit 516 is, for example, a circuit with a variable line length. Accordingly, even in the presence of variations in circuit constant or circuit size, the phase of the second harmonic H1 in the second coupling unit 512, and the phase of the second harmonic H4 in the second coupling unit 512 can be aligned with each other through adjustment of the amount of delay.

The variable phase shifter 517 is a circuit capable of adjusting the amount of phase shift of the second harmonic H3. Accordingly, even in the presence of variations in circuit constant or circuit size, the phase of the second harmonic H3 can be shifted by approximately 180 degrees through adjustment of the amount of phase shift. As a result, the amplitude of the second harmonic H1 and the amplitude of the second harmonic H4 can be made to have opposite signs in the second coupling unit 512.

The variable attenuator 518 is a circuit capable of adjusting the amount of attenuation of the power of the second harmonic H3. Accordingly, even in the presence of variations in circuit constant or circuit size, the power of the second harmonic H4 that is output from the first port of the main line 512b can be made substantially equal to the power of the second harmonic H1 that is input to the main line 512b.

### Sixth Embodiment

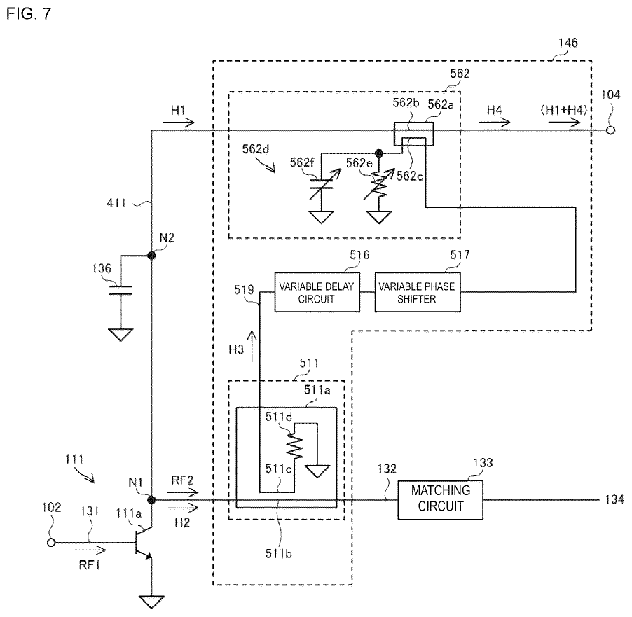

The power amplifier circuit 11 according to a sixth exemplary embodiment is described below. FIG. 7 is a circuit diagram of a harmonic suppression circuit 146 and circuitry in its vicinity in the front-end module 101. As illustrated in FIG. 7, the power amplifier circuit 11 according to the seventh exemplary embodiment differs from the power amplifier circuit 11 according to the sixth exemplary embodiment in that in a second coupling unit 562 of the harmonic suppression circuit 146, the amount of electromagnetic coupling between the power supply line 411 and a sub-line is adjustable.

As compared with the harmonic suppression circuit 145 illustrated in FIG. 6, the harmonic suppression circuit 146 includes the second coupling unit 562, instead of the second coupling unit 512 and the variable attenuator 518.

The second coupling unit 562 includes a directional coupler 562a disposed on the power supply line 411 between the node N2 and the power supply terminal 104.

The directional coupler 562a includes a main line 562b, a sub-line 562c (third sub-line), and a variable impedance circuit 562d. The main line 562b constitutes a portion of the power supply line 411. The sub-line 562c electromagnetically couples to the main line 562b.

The main line 562b has a first port and a second port. The first port is connected to the power supply terminal 104. The second port is connected to the node N2. The sub-line 562c has a third port and a fourth port. The third port is connected to the second end of the suppression signal line 519. The fourth port is connected to the variable impedance circuit 562d.

Due to the connection of the variable impedance circuit 562d to the fourth port of the sub-line 562c, the sub-line 562c has a variable termination impedance. According to the sixth exemplary embodiment, the variable impedance circuit 562d includes a variable resistance element 562e and a variable capacitor 562f.

The variable resistance element 562e has a first end connected to the fourth port of the sub-line 562c, and a second end connected to ground. The variable capacitor 562f has a first end connected to the first end of the variable resistance element 562e, and a second end connected to ground.

Adjusting at least one of the resistance of the variable resistance element 562e and the capacitance of the variable capacitor 562f makes it possible to adjust the directivity and isolation of the directional coupler 562a.

That is, even with no attenuator provided, the power of the second harmonic H4 that is output from the first port of the main line 512b can be made substantially equal to the power of the second harmonic H1 that is input to the main line 512b, through adjustment of the variable impedance circuit 562d. As a result, through simple configuration, the second harmonic H1 that is transferred to the power supply line 411 can be effectively suppressed by means of the second harmonic H4.

In the foregoing description of the harmonic suppression circuit 141, 142, 143, 144, 145, or 146, the second harmonic H4 is output to the power supply line 411 as a suppression signal. This configuration, however, is not intended to be limiting. In an alternative configuration, the second harmonic H4 may be output to at least one of the power supply lines 411, 413b, 413c, and 412.

In the foregoing descriptions of the harmonic suppression circuit 141, 142, 143, 144, 145, or 146, the second coupling unit 512, 532, 542, or 562 is disposed on the power supply line 411. This configuration, however, is not intended to be limiting. In an alternative configuration, the second coupling unit 512, 532, 542, or 562 may be located on at least one of the power supply lines 411, 413b, 413c, and 412.

In the foregoing descriptions of the harmonic suppression circuit 141, 142, 143, or 144, the delay circuit 513 is disposed on the suppression signal line 519. This configuration, however, is not intended to be limiting. In an alternative configuration, instead of the delay circuit 513, the variable delay circuit 516 may be disposed on the suppression signal line 519.

In the foregoing descriptions of the harmonic suppression circuits 141, 143, and 144, the phase shifter 514 is disposed on the suppression signal line 519. This configuration, however, is not intended to be limiting. In an alternative configuration, instead of the phase shifter 514, the variable phase shifter 517 may be disposed on the suppression signal line 519.

In the foregoing descriptions of the harmonic suppression circuits 141, 143, and 144, the attenuator 515 is disposed on the suppression signal line 519. This configuration, however, is not intended to be limiting. In an alternative configuration, instead of the attenuator 515, the variable attenuator 518 may be disposed on the suppression signal line 519.

In the foregoing description of the harmonic suppression circuit 146, the variable delay circuit 516 is disposed on the suppression signal line 519. This configuration, however, is not intended to be limiting. In an alternative configuration, instead of the variable delay circuit 516, the delay circuit 513 may be disposed on the suppression signal line 519.

In the foregoing description of the harmonic suppression circuit 146, the variable phase shifter 517 is disposed on the suppression signal line 519. This configuration, however, is not intended to be limiting. In an alternative configuration, instead of the variable phase shifter 517, the phase shifter 514 may be disposed on the suppression signal line 519.

Illustrative exemplary embodiments of the present disclosure have been described above. In the power amplifier circuit 11, the power amplifier 111 is capable of operating on power supplied through the power supply lines 411 and 413b. The power amplifier 111 amplifies a first transmit signal in a first frequency band. In the power amplifier 211, the power amplifier 211 is capable of operating on power supplied through the power supply lines 413c and 412 connected to the power supply lines 411 and 413b. The power amplifier 211 amplifies a second transmit signal in a second frequency band different from the first frequency band. The low noise amplifier 221 shares the antenna 235 with the power amplifier 211, and amplifies a receive signal in the second frequency band received from the antenna 235. The harmonic suppression circuit generates, based on a harmonic of the first transmit signal, a suppression signal for suppressing a harmonic to be transferred to the power supply lines 411 and 413b, and outputs the suppression signal to the power supply line 411, 413b, 413c, or 412.

The harmonic to be transferred to the power supply lines 411, 413b, 413c, and 412 is based on the first transmit signal. Generating a suppression signal based on the harmonic of the first transmit signal in this way allows for easy generation of a suppression signal that is suited for suppression of the harmonic to be transferred to the power supply lines 411 and 413b. The suppression signal is output to the power supply line 411, 413b, 413c, or 412 to which a harmonic that can adversely affect the low noise amplifier 221 is transferred. This configuration makes it possible to reduce the power of the harmonic to be transferred from the power amplifier 111 to the power amplifier 211. Since the power amplifier 211 and the low noise amplifier 221 share the antenna 235, the power of the harmonic to be transferred from the power amplifier 211 to the low noise amplifier 221 can be also reduced. This makes it possible to reduce performance degradation of the power amplifier 211 and the low noise amplifier 221. Therefore, for a configuration including the power amplifier 111 that amplifies the first transmit signal in the first frequency band, and the power amplifier 211 and the low noise amplifier 221 that respectively amplify the second transmit signal and the receive signal in the second frequency band different from the first frequency band, noise that is transferred from the power amplifier 111 to the power amplifier 211 and the low noise amplifier 221 can be suppressed.

In the power amplifier circuit 11, the first frequency band is lower than the second frequency band.

If the first frequency band is lower than the second frequency band, a harmonic of the first transmit signal in the first frequency band often becomes noise for the second transmit signal and the receive signal that are in the second frequency band. In this regard, the ability to suppress the harmonic to be transferred to the power supply lines 411, 413b, 413c, and 412 makes it possible to effectively reduce performance degradation of the power amplifier 211 and the low noise amplifier 221.

In the harmonic suppression circuit 141 or the harmonic suppression circuit 143, 144, 145, or 146 of the power amplifier circuit 11, the first coupling unit couples to the signal line 132 that transfers the RF signal RF1 amplified by the power amplifier 111. The second coupling unit couples to the power supply line 411, 413b, 413c, or 412. The phase shifter 514 is disposed between the first coupling unit and the second coupling unit. The attenuator 515 is disposed between the first coupling unit and the second coupling unit.

As a result of the configuration mentioned above, a harmonic suppression circuit that generates a suppression signal can be easily implemented by passive elements.

In the harmonic suppression circuit 143, the first coupling unit 531 includes the resistance element 531a. The resistance element 531a has a first end connected to the signal line 132, and a second end. The second coupling unit 532 includes the resistance element 532a. The resistance element 532a has a first end and a second end. The first end of the resistance element 532a is connected to the second end of the resistance element 531a through the phase shifter 514 and the attenuator 515. The second end of the resistance element 532a is connected to the power supply line 411, 413b, 413c, or 412.

As described above, the harmonic suppression circuit 143 is connected to the signal line 132 through the resistance element 531a. This configuration allows for reduced size of the first coupling unit 531 while ensuring isolation of the harmonic suppression circuit 143 from the signal line 132. Further, the harmonic suppression circuit 143 is connected to the power supply line 411, 413b, 413c, or 412 through the resistance element 532a. This configuration allows for reduced size of the second coupling unit 532 while suppressing unwanted current flow from the power supply line 411, 413b, 413c, or 412 into the harmonic suppression circuit 143.

In the harmonic suppression circuit 144, the first coupling unit 541 includes the capacitor 541a. The capacitor 541a has a first end and a second end. The first end is connected to the signal line 132. The second coupling unit 542 includes the capacitor 542a. The capacitor 542a has a first end and a second end. The first end is connected to the second end of the capacitor 541a through the phase shifter 514 and the attenuator 515. The second end is connected to the power supply line 411, 413b, 413c, or 412.

As described above, the harmonic suppression circuit 144 is provided at opposite ends with the capacitors 541a and 542a. This configuration makes it possible to prevent direct-current components from being transferred between the power supply line 411, 413b, 413c, or 412, and the signal line 132. As for alternating-current components, a configuration can be achieved in which, between the power supply line 411, 413b, 413c, or 412 and the signal line 132, a harmonic is transferred while transfer of the fundamental component is suppressed. Adjusting the power of the harmonic by means of the attenuator 515 makes it possible to generate a suppression signal suited for suppression of the second harmonic H1. Further, the first coupling unit 541 and the second coupling unit 542 can be reduced in size.

In the harmonic suppression circuit 141, the first coupling unit 511 includes the sub-line 511c that electromagnetically couples to the signal line 132. The second coupling unit 512 includes the sub-line 512c that electromagnetically couples to the power supply line 411, 413b, 413c, or 412, and that is connected to the sub-line 511c.

As a result of the configuration mentioned above, based on the second harmonic H2 directed from the first port of the main line 511b toward the second port of the main line 511b on the signal line 132, the second harmonic H3 can be efficiently output from the third port of the sub-line 511c, which is an isolated port opposite from the fourth port of the sub-line 511c. The configuration mentioned above also makes it possible to efficiently output the second harmonic H4 in the same direction as the direction in which the second harmonic H1 is transferred in a portion of the power supply line 411, 413b, 413c, or 412 corresponding to the main line 512b. This allows for efficient suppression of the second harmonic H1.

The amplified signal RF2 before undergoing amplification by the power-stage transistor 111c, that is, the amplified signal RF3, and the amplified signal RF2 after undergoing amplification by the power-stage transistor 111c are opposite in phase to each other. In the harmonic suppression circuit 142, the first coupling unit 521 includes the resistance element 521a. The resistance element 521a has a first end and a second end. The first end is connected to the signal line 137 through which the amplified signal RF3 before undergoing amplification by the power-stage transistor 111c is transferred. The second coupling unit 512 includes the sub-line 512c. The sub-line 512c is connected to the second end of the resistance element 521a, and electromagnetically couples to the power supply line 411, 413b, 413c, or 412.

As described above, the harmonic suppression circuit 142 is connected to the signal line 137 through the resistance element 521a. This configuration allows for reduced size of the first coupling unit 521 while ensuring isolation of the harmonic suppression circuit 142 from the signal line 137. The harmonic suppression circuit 142 is connected to the signal line 137 through which the amplified signal RF3 before undergoing amplification by the power-stage transistor 111c is transferred. This configuration makes it possible to reduce the power of the second harmonic H6 flowing in the harmonic suppression circuit 142. Consequently, the power of the second harmonic H1 that is transferred to the power supply line 411, 413b, 413c, or 412, and the power of the second harmonic H4 that is generated on the power supply line based on the second harmonic H6, that is, the power of the suppression signal, can be made substantially equal, even with no attenuator provided to attenuate power. Further, the amplified signal RF3 before undergoing amplification by the power-stage transistor 111c, and the amplified signal RF2 after undergoing amplification by the power-stage transistor 111c are opposite in phase to each other. This configuration makes it possible to provide a phase shift of approximately 180 degrees between the second harmonic H1 and a suppression signal even with no phase shifter 514 provided. That is, a suppression signal suited for suppression of the second harmonic H1 can be generated through simple configuration.

The driver-stage transistor 111b is connected to the power-stage transistor 111c through the signal line 137.

As a result of the configuration mentioned above, even when the driver-stage transistor 111b and the power-stage transistor 111c are positioned so as to reduce the inter-stage spacing, the first coupling unit 521 having a small size can be connected between the driver-stage transistor 111b and the power-stage transistor 111c. This makes it possible to achieve a two-stage amplifier with a small size.

In the harmonic suppression circuit 146, the first coupling unit 511 includes the sub-line 511c that electromagnetically couples to the signal line 132 through which the RF signal RF1 amplified by the power amplifier 111 is transferred. The second coupling unit 562 includes the sub-line 562c that electromagnetically couples to the power supply line 411, 413b, 413c, or 412. The variable phase shifter 517 is disposed between the first coupling unit 511 and the second coupling unit 562. The sub-line 562c has a variable termination impedance.

The configuration mentioned above allows the directivity and isolation between the signal line 132 and the sub-line 562c to be adjusted by means of the termination impedance. Consequently, the power of the second harmonic H1 that is transferred to the power supply line 411, 413b, 413c, or 412, and the power of the second harmonic H4 that is generated on the power supply line based on the second harmonic H3 flowing in the harmonic suppression circuit 146, that is, the power of the suppression signal, can be made substantially equal, even with no attenuator provided to attenuate power. That is, a suppression signal suited for suppression of the second harmonic H1 can be generated through simple configuration.

In the harmonic suppression circuit 145, the variable phase shifter 517 provides a variable amount of phase shift.

As a result of the configuration mentioned above, even in the presence of variations in the phase of the second harmonic H1, adjusting the amount of phase shift makes it possible to reduce the likelihood that such variations may result in insufficient suppression of the second harmonic H1.

In the power amplifier circuit 11, the matching circuit 133 is disposed on the signal line 132. The first coupling unit 511, 531, or 541 couples to the signal line 132 between the power amplifier 111 and the matching circuit 133.

As a result of the configuration mentioned above, the second harmonic H2 of the amplified signal RF2 before undergoing attenuation by the matching circuit 133 can be transferred to the harmonic suppression circuit 141 or the harmonic suppression circuit 143, 144, 145, or 146. This makes it possible to generate a suppression signal having a sufficient power for suppressing the second harmonic H1.

In the power amplifier circuit 11, the capacitor 136 has a first end and a second end. The first end is connected between the power amplifier 111 and the second coupling unit 512, 532, 542, or 562. The second end is connected to ground.

As a result of the configuration mentioned above, a portion of the harmonic that is transferred from the power amplifier 111 to the second coupling unit 512, 532, 542, or 562 can be passed to ground through the capacitor 136. This makes it possible to reduce the power of the harmonic in the second coupling unit 512, 532, 542, or 562 to a level that allows the harmonic to be effectively suppressed by a suppression signal.

In the harmonic suppression circuit 141, 142, 143, 144, 145, or 146, the delay circuit 513 or the variable delay circuit 516 is disposed between the first coupling unit and the second coupling unit.

As a result of the configuration mentioned above, in the second coupling unit, the second harmonic H1 that is transferred to the power supply line 411, 413b, 413c, or 412, and the suppression signal from the harmonic suppression circuit 141, 142, 143, 144, 145, or 146 can be aligned in phase with each other. This makes it possible to effectively suppress the second harmonic H1 that is transferred to the power supply line 411, 413b, 413c, or 412.

In the harmonic suppression circuit 145 or 146, the variable delay circuit 516 provides a variable amount of delay.

As a result of the configuration mentioned above, even in the presence of variations in the phase of the second harmonic H1 in the second coupling unit 512, adjusting the amount of delay allows the suppression signal to have a phase suitable for suppressing the second harmonic H1 that is transferred to the power supply line 411, 413b, 413c, or 412. That is, the configuration mentioned above makes it possible to reduce the likelihood that such variations may result in insufficient suppression of the second harmonic H1.

In the power amplifier circuit 11, amplification of the RF signal RF1 by the power amplifier 111, and amplification of the receive signal by the low noise amplifier 221 occur simultaneously.

The configuration mentioned above makes it possible to suppress the harmonic of the first transmit signal that is transferred to the low noise amplifier 221. As a result, for example, even when transmission of the first transmit signal and reception of the receive signal take place simultaneously as in the case of carrier aggregation or EN-DC, mixing of the harmonic into the receive signal can be reduced. This makes it possible to reduce degradation of reception sensitivity.

In the harmonic suppression circuit 145, the variable attenuator 518 provides a variable amount of attenuation.

As a result of the configuration mentioned above, even in the presence of variations in the power of the second harmonic H1, adjusting the amount of attenuation makes it possible to reduce the likelihood that such variations may result in insufficient suppression of the second harmonic H1.

The exemplary embodiments described above are intended to facilitate understanding of the present disclosure, and not to be construed as limiting of the present disclosure. The present disclosure allows various changes/modifications to be made without departing from its spirit and scope, and the present disclosure encompasses equivalents thereof. That is, the exemplary embodiments with suitable design variations made thereto by those skilled in the art also fall within the scope of the present disclosure as long as the resulting exemplary embodiments include the characteristic features of the present disclosure. For example, individual elements included in the exemplary embodiments, and their associated arrangements, materials, conditions, shapes, sizes, or other specific details are not limited to those illustrated but may be changed as appropriate. It is needless to mention that the exemplary embodiments are for illustrative purpose, and partial substitutions or combinations of features described in different exemplary embodiments are possible. Such substitutions or combinations of features also fall within the scope of the present disclosure as long as the resulting exemplary embodiments include the characteristic features of the present disclosure.

### REFERENCE SIGNS LIST

1 communication device
11 power amplifier circuit
101 front-end module
111 power amplifier
111a amplifier transistor
111b driver-stage transistor
111c power-stage transistor
121 low noise amplifier
131, 132 signal line
133 matching circuit
134 duplexer
135 antenna
136 capacitor
137 signal line
141, 142, 143, 144, 145, 146 harmonic suppression
circuit
201 front-end module
211 power amplifier
221 low noise amplifier
231, 232 signal line
233 matching circuit
234 duplexer
235 antenna
236 capacitor
241 harmonic suppression circuit
301 front-end module
401 PMIC
411, 412, 413a, 413b, 413c power supply line
421 ETM
431, 432, 433a, 433b, 433c power supply line
511, 521, 531, 541 first coupling unit
512, 532, 542, 562 second coupling unit
513 delay circuit
514 phase shifter
515 attenuator
516 variable delay circuit
517 variable phase shifter
518 variable attenuator
519 suppression signal line

1. A power amplifier circuit comprising:
a first amplifier that operates on power supplied through a first supply line, and that amplifies a first transmit signal in a first frequency band;
a second amplifier that operates on power supplied through a second supply line connected to the first supply line, and that amplifies a second transmit signal in a second frequency band different from the first frequency band;
a third amplifier that shares an antenna with the second amplifier, and that amplifies a receive signal in the second frequency band received from the antenna; and
a harmonic suppression circuit that, based on a harmonic of the first transmit signal, generates a suppression signal to suppress the harmonic to be transferred to the first supply line, and outputs the suppression signal to the first supply line or the second supply line.

2. The power amplifier circuit according to claim 1,
wherein the first frequency band is lower than the second frequency band.

3. The power amplifier circuit according to claim 1,
wherein the harmonic suppression circuit includes
a first coupler that couples to a signal line through which the first transmit signal amplified by the
first amplifier is transferred,
a second coupler that couples to the first supply line or the second supply line,
a phase shifting circuit disposed between the first coupler and the second coupler, and
an attenuation circuit disposed between the first coupler and the second coupler.

4. The power amplifier circuit according to claim 3,
wherein the first coupler includes a first resistance element, the first resistance element including
a first end connected to the signal line, and
a second end, and
wherein the second coupler includes a second resistance element, the second resistance element including
a first end connected to the second end of the first resistance element through the phase shifting circuit and the attenuation circuit, and
a second end connected to the first supply line or the second supply line.

5. The power amplifier circuit according to claim 3,
wherein the first coupler includes a first capacitor, the first capacitor including
a first end connected to the signal line, and
a second end, and
wherein the second coupler includes a second capacitor, the second capacitor including
a first end connected to the second end of the first capacitor through the phase shifting circuit and the attenuation circuit, and
a second end connected to the first supply line or the second supply line.

6. The power amplifier circuit according to claim 3,
wherein the first coupler includes a first sub-line that electromagnetically couples to the signal line, and
wherein the second coupler includes a second sub-line that electromagnetically couples to the first supply line or the second supply line, and that is connected to the first sub-line.

7. The power amplifier circuit according to claim 1,
wherein the first transmit signal before undergoing amplification by the first amplifier, and the first transmit signal after undergoing amplification by the first amplifier are opposite in phase, and
wherein the harmonic suppression circuit includes
a first coupler including a third resistance element, the third resistance element including
a first end connected to a signal line through which the first transmit signal before undergoing amplification by the first amplifier is transferred, and
a second end, and
a second coupler including a second sub-line that is connected to the second end of the third resistance element, and that electromagnetically couples to the first supply line or the second supply line.

8. The power amplifier circuit according to claim 7, further comprising:
a fourth amplifier connected to the first amplifier through the signal line.

9. The power amplifier circuit according to claim 1,
wherein the harmonic suppression circuit includes
a first coupler including a first sub-line that electromagnetically couples to a signal line through which the first transmit signal amplified by the first amplifier is transferred,
a second coupler including a third sub-line that electromagnetically couples to the first supply line or the second supply line, and
a variable phase shifting circuit disposed between the first coupler and the second coupler, and
wherein the third sub-line has a variable termination impedance.

10. The power amplifier circuit according to claim 3,
wherein the phase shifting circuit provides a variable amount of phase shift.

11. The power amplifier circuit according to claim 3, further comprising:
a matching circuit disposed on the signal line,
wherein the first coupler couples to the signal line between the first amplifier and the matching circuit.

12. The power amplifier circuit according to claim 3, further comprising:
a third capacitor having
a first end connected between the first amplifier and the second coupler, and
a second end connected to ground.

13. The power amplifier circuit according to claim 3,
wherein the harmonic suppression circuit further includes
a delay circuit disposed between the first coupler and the second coupler.

14. The power amplifier circuit according to claim 13,
wherein the delay circuit provides a variable amount of delay.

15. The power amplifier circuit according to claim 1,
wherein amplification of the first transmit signal by the first amplifier, and amplification of the receive signal by the third amplifier occur simultaneously.

16. A power amplifier circuit comprising:
a first amplifier that receives supply of power through a first supply line, and that amplifies a first transmit signal in a first frequency band;
a second amplifier that receives supply of power through a second supply line connected to the first supply line, and that amplifies a second transmit signal in a second frequency band different from the first frequency band;
a third amplifier that shares an antenna with the second amplifier, and that amplifies a receive signal in the second frequency band received from the antenna;
a first coupler that couples to a signal line through which the first transmit signal amplified by the first amplifier is transferred;
a second coupler that couples to the first supply line or the second supply line;
a phase shifting circuit disposed between the first coupler and the second coupler; and
an attenuation circuit disposed between the first coupler and the second coupler.

17. A power amplifier circuit comprising:
a first amplifier that receives supply of power through a first supply line, and that amplifies a first transmit signal in a first frequency band;
a second amplifier that receives supply of power through a second supply line connected to the first supply line, and that amplifies a second transmit signal in a second frequency band different from the first frequency band;
a third amplifier that shares an antenna with the second amplifier, and that amplifies a receive signal in the second frequency band received from the antenna;
a first coupler including a third resistance element, the third resistance element including
a first end connected to an input of the first amplifier, and
a second end; and
a second coupler including a second sub-line that is connected to the second end of the third resistance element, and that electromagnetically couples to the first supply line or the second supply line.

18. The power amplifier circuit according to claim 17,
wherein the first transmit signal before undergoing amplification by the first amplifier, and the first transmit signal after undergoing amplification by the first amplifier are opposite in phase.

19. The power amplifier circuit according to claim 16,
wherein the first frequency band is lower than the second frequency band.

20. The power amplifier circuit according to claim 3,
wherein the attenuation circuit provides a variable amount of attenuation.
